(19) United States
(12) Patent Application Publication
(10) Pub. No.: US 2026/0302301 A1
(43) Pub. Date: Oct. 1, 2026

(54) METHOD FOR MONITORING THE STATE OF A REDOX FLOW BATTERY SYSTEM

(71) Applicant: LIVA Power Management Systems GmbH, Frankfurt am Main (DE)

(72) Inventors: Thomas Lüth, Freiburg (DE); Yifeng Li, Steinheim (DE)

(21) Appl. No.: 19/476,092

(22) PCT Filed: Apr. 16, 2024
(86) PCT No.: PCT/EP2024/060269

§ 371 Date: Oct. 16, 2025

(30) Foreign Application Priority Data
Apr. 17, 2023 (DE) 10 2023 109 591.9

(51) Int. Cl. H01M 8/18; H01M 8/04537; H01M 8/04746; H01M 8/04858

(52) U.S. Cl. CPC H01M 8/18; H01M 8/04559; H01M 8/04589; H01M 8/04776; H01M 8/0491

(57) ABSTRACT

A method for monitoring the state of a vanadium based redox flow battery system includes at least two battery modules, a bidirectional converter, and a control device. The battery modules are connected in series to the bidirectional converter. Each battery module has a cell arrangement having a plurality of redox flow cells, a measurement device for detecting a potential difference, and a reservoir for storing and supplying the cell arrangement with electrolyte. The method includes: identifying at least one battery module with suspected shifted electrolyte; switching off the pumps of the at least one identified battery module at a time t1 while the battery system is in the “discharge” operating state; repeatedly detecting potential difference values at the at least one identified battery module up to a later time t2; and determining the AOS of the at least one identified battery module from the potential difference values.

### CROSS REFERENCE TO RELATED APPLICATION

This application is a national stage application of International Patent Application No. PCT/EP2024/060269, filed on Apr. 16, 2024, which claims priority to German Patent Application No. 102023109591.9 titled “Verfahren zur Zustandsüberwachung eines Redox-Flow-Batterie-Systems” filed with the German Patent Office on Apr. 17, 2023, each of which is incorporated herein by reference in its entirety.

### TECHNICAL FIELD

The invention relates to a method for operating a redox flow battery system on the basis of vanadium. The invention relates in particular to redox flow battery systems with a high output voltage. The operating method relates to monitoring the state of health (SoH) of the battery system.

### BACKGROUND

In order to obtain a high output voltage in redox flow battery systems, several cells are usually connected electrically in series. This arrangement is called a stack. However, this cannot be continued indefinitely, as otherwise the shunt current caused by the electrolyte fluid would become intolerably high. However, the output voltage may be further increased by connecting several stacks in series, with each stack having a separate tank unit. Such a unit consisting of a stack and an associated separate tank unit is called a battery module. The series connection of several battery modules is conventionally referred to as a string. The invention therefore relates to a battery system comprising several battery modules, wherein the battery system is configured such that during charging and discharging of the system, the battery modules are connected in series, i.e. form a string.

The SoH of a redox flow battery system may be negatively influenced by various effects. An imbalance in the electrolyte, which consists of an unequal ion concentration in the negative and positive electrolytes, may have a negative effect on the SoH. Such an imbalance is usually described by the average oxidation state (AOS). An AOS that deviates from +3.5 indicates such an imbalance. Such an imbalance may already exist at the start of operation or become more pronounced during operation. The latter may be caused by vanadium oxidation, other chemical side reactions and by “crossover” at the membranes of the stacks. Such an imbalance in the electrolyte is also often referred to as electrolyte shift. A battery module affected by this is referred to below as a “battery module with shifted electrolyte”.

Another possible cause of electrolyte imbalance is that the volume of the negative electrolyte may differ from the volume of the positive electrolyte. The total electrolyte volume of a battery module and/or the electrolyte volume in the cells may exhibit such a deviation. In the latter case, this may be caused by an air bubble in one or more cells, for example. An imbalance caused by different electrolyte volumes may also increase over time. An electrolyte imbalance based on a deviation in the total electrolyte volume of a battery module cannot be detected using the method according to the invention.

Methods for monitoring the state of a redox flow battery system are known from the prior art. For example, DE 10 2020 123 170 A1 discloses such a method in which a battery module is disconnected from the series connection and at least a partial volume of the electrolyte of the disconnected battery module is discharged, wherein a potential difference is repeatedly measured. The AOS is then determined from any steps in the potential difference curves.

### SUMMARY

The object of the invention is to provide an alternative method for monitoring the state of a redox flow battery system, which makes it possible to detect an imbalance in the electrolyte that is not due to a deviation in the total electrolyte volume of a battery module, and which may be carried out more easily than the methods known from the prior art.

The object is achieved in accordance with the invention by means of an embodiment according to the independent claim. Further advantageous embodiments of the present invention are found in the dependent claims.

### BRIEF DESCRIPTION OF THE DRAWINGS

The invention is explained below with reference to the figures. The figures show in detail:

FIG. 1 a battery module

FIG. 2 a battery system

FIG. 3 a time curve of the terminal voltage during the method according to the invention in a first embodiment;

FIG. 4 a time curve of the terminal voltage during the method according to the invention in a second embodiment;

### DETAILED DESCRIPTION

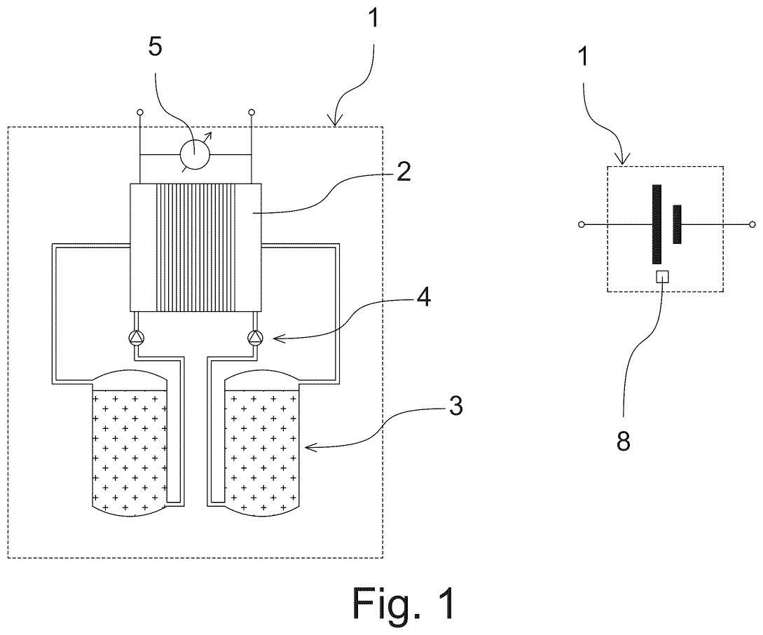

FIG. 1 shows a schematic representation of a battery module on the left-hand side. The battery module is designated 1. The battery module comprises a cell arrangement, designated 2, and a reservoir, designated 3. The cell arrangement 2 is an arrangement of a plurality of redox flow cells, which may be arranged in any manner. For example, it could be a single cell stack, a series connection of several stacks, a parallel connection of several stacks, or a combination of series and parallel connections of several stacks. The reservoir 3 is used to store electrolyte fluid and to supply the cell arrangement 2 with electrolyte fluid. For this purpose, the reservoir 3 comprises at least two tanks for negative and positive electrolyte, a pipe system for connecting the tanks to the cell arrangement 2, and pumps for conveying the electrolyte, one of which is designated 4. FIG. 1 shows two separate pumps 4. The electrolyte fluid could just as easily be conveyed by a double-head pump, i.e. by two pumps 4 driven by a common motor. The reservoir 3 is configured so that it may supply all cells of the cell arrangement 2 with electrolyte fluid. When the pumps 4 convey electrolyte fluid, all cells of the cell arrangement 2 are flowed through by said fluid.

The battery module 1 shown in FIG. 1 comprises a measurement device for providing a potential difference, which is designated 5. The measurement device 5 measures a potential difference which is formed between a first potential of the negative electrolyte and a second potential of the positive electrolyte. In the measurement device 5 for providing a potential difference, the electrodes for detecting the aforementioned potentials are located in corresponding cells of the cell arrangement 2. The potential difference formed depends on the number of cells connected in series between the electrodes for detecting the potentials. Since redox flow battery modules usually include a measurement device that may detect and provide a potential difference between the two outer electrodes of the cell arrangement 2, it is easiest to use this measurement device. The described potential difference between the two outer electrodes is referred to as the terminal voltage.

A symbolic representation of the battery module 1 is shown on the right-hand side of FIG. 1. This symbolic representation is used in the following. To implement a special embodiment of the method according to the invention, each battery module 1 comprises a polarity reversal device. The outer terminals, which are indicated by the small circles in FIG. 1, are connected crosswise with respect to the inner terminals, i.e. the electrical connections of the cell arrangement 2, so that the polarity of the outer terminals is reversed for a given electrical polarity of the cell arrangement. This polarity reversal device is indicated on the right-hand side of FIG. 1 by the small rectangle designated 8.

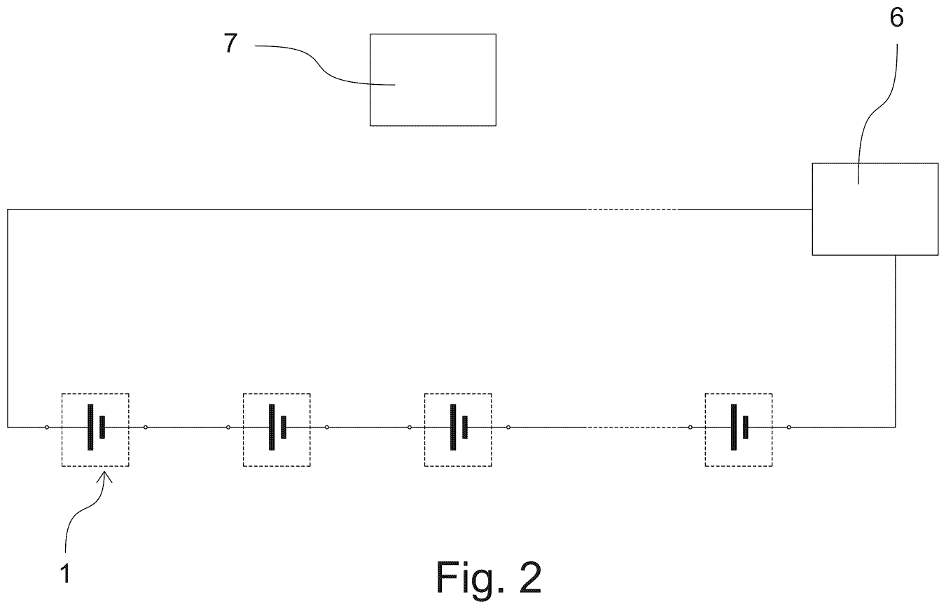

FIG. 2 shows a schematic representation of a battery system. The battery system comprises at least two battery modules, one of which is designated 1, a bidirectional power conversion system (PCS), which is designated 6, and a control device, which is designated 7. The battery modules 1 are connected in series and are connected to the converter 6. FIG. 2 shows four battery modules, wherein the dotted lines in the series connection indicate any number of additional modules. The converter 6 connects the battery system to the mains or to a higher-level electrical system. The control device 7 is configured to detect the operating state of the converter 6 and control the pumps 4 in the battery modules 1. The operating states of the converter 6 include, for example, the states “charging the battery system” and “discharging the battery system”. Optionally, the control device 7 may be configured so that it may additionally detect the measured values of the measurement devices to provide a potential difference 5 of the battery modules 1.

The method according to the invention is described below. The terminal voltage is used as the potential difference. In addition, a sign convention is used according to which the terminal voltage of the battery modules has a positive sign during normal operation of the battery system. A corresponding convention applies if a potential difference other than the terminal voltage is used.

The method according to the invention for monitoring the state of a redox flow battery system comprises the following steps in the order indicated:
S1: identifying at least one battery module 1 with a suspicion of shifted electrolyte;
S2: switching off the pumps 4 of the at least one identified battery module 1 at a time t₁ while the battery system is in the “discharging” operating state;
S3: repeatedly detecting terminal voltage values at the at least one identified battery module 1 until a (later) time t₂, with the pumps 4 remaining switched off;
S4: determining the AOS of the at least one identified battery module 1 from the terminal voltage values detected in step S3,
   where the length of the time interval At=t₂-t₁ is selected such that at time t₂ the terminal voltage of the at least one identified battery module 1 is negative, but overcharging of the electrolyte located in the cell arrangement 2 of the at least one identified battery module 1 is avoided, and wherein the battery system is discharged in the time interval [t₁, t₂].

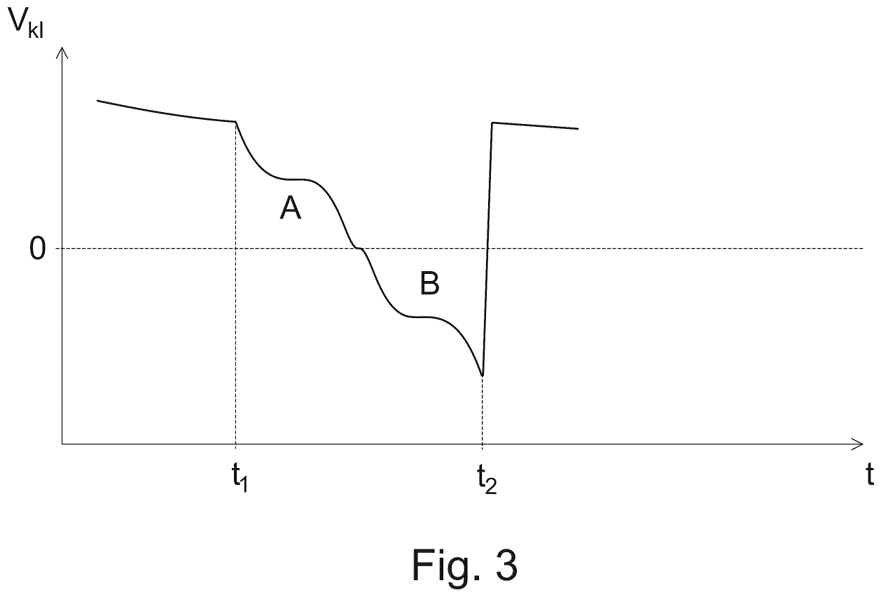

For a detailed description of step S4, reference is made to paragraphs [0027] to [0030] of DE 10 2020 123 170 A1. The aforementioned paragraphs are considered part of this document. The terminal voltage values detected in step S3 function as potential difference values. In addition, the determination of the SoH or AOS described in DE 10 2020 123 170 A1 is transferred analogously to the range in which the terminal voltage is negative. This is explained in more detail below in conjunction with FIG. 3.

The first step, i.e. the identification of at least one battery module with displaced electrolytes, may be carried out during any operating state of the battery system, i.e. both while the battery system is being charged and while the battery system is being discharged. The other steps, on the other hand, may only be carried out when the battery system is being discharged. The identification step is a step used to check whether the subsequent steps of the method according to the invention are to be carried out on a battery module. This means that the method according to the invention in the narrower sense consists of the steps mentioned after the identification step. In some of the following explanations, the term “method according to the invention” is used in this narrower sense. This is the case when it is clear from the context that one or more battery modules have already been identified.

A battery module is suspected of having a shifted electrolyte if there is a reduction in the usable capacity of the battery module in question. This may be detected, for example, if the battery module in question is charged or discharged more quickly than the other battery modules in the battery system, even though all battery modules are discharged or charged by the same current (series connection of the battery modules).

The electrochemical processes that take place in the degraded battery module in question during the execution of the method according to the invention are explained in more detail with reference to FIG. 3.

FIG. 3 shows the time curve of the terminal voltage of a battery module with displaced electrolyte during the execution of the method according to the invention. Before the time t₁, the battery module in question participates in the discharge process of the battery system like any other battery module in the battery system. The terminal voltage drops over time because the electrolyte conveyed by the pumps through the cell arrangement is partially discharged while it remains in the cell arrangement. When the pumps are switched off at time t₁, the supply of electrolyte to the cell arrangement stops, and the electrolyte permanently located in the cell arrangement during this state is therefore discharged much more quickly, since the discharge current flowing through the battery modules connected in series is not changed or is only negligibly changed by the process. The terminal voltage of the degraded battery module drops just as quickly. When the terminal voltage reaches zero, the electrolyte in the cell arrangement is charged in the opposite direction and the terminal voltage of the battery module in question therefore becomes negative. This is an electrochemical characteristic specific to vanadium electrolytes. However, the charging process with the opposite sign cannot be continued indefinitely, as this would overload the electrolyte in the cell arrangement, which would damage the battery module. The pumps are therefore switched on again at a selected time t₂. Fresh electrolyte now flows into the cell arrangement again. This supplied electrolyte has a state of charge similar to that shortly before time t₁, so that the terminal voltage rises again to the (positive) value corresponding to t₁. In the curve shown in FIG. 3, the pumps are operated at the same flow rate as before time t₁. However, this is not a necessary condition. Rather, it is only intended to express that the battery module in question returns to normal operation at time t₂. If, for any reason, normal operation of the battery module at time t₂ requires a different pump rate than it did shortly before time t₁, the pumps would be operated at the pump rate required at that time at time t₂. Alternatively, the battery module in question may also be removed from the series connection of the battery system, e.g. if the AOS determination has delivered a result that requires immediate maintenance.

In the range between time t₁ and the zero crossing, a plateau marked A can be seen in the terminal voltage curve Vₖₗ(t). In the area between the zero crossing and time to, i.e. in the negative terminal voltage range, another plateau can be seen in the terminal voltage curve Vₖₗ(t), which is marked with B. Any plateau A in the positive range of the terminal voltage may be used to determine the SoH or AOS in the same way as described in DE 10 2020 123 170 A1. Any plateau B in the negative range of the terminal voltage may be used in a similar way to determine the AOS. The method according to the invention enables the determination of the AOS to be carried out in both the positive and negative range of the terminal voltage, thereby allowing redundant determination of the AOS and thus ensuring greater reliability of the determination of the AOS and thus of the SoH. For this purpose, the time point t₂ must be selected so that any plateau B in the negative range of the terminal voltage may be detected.

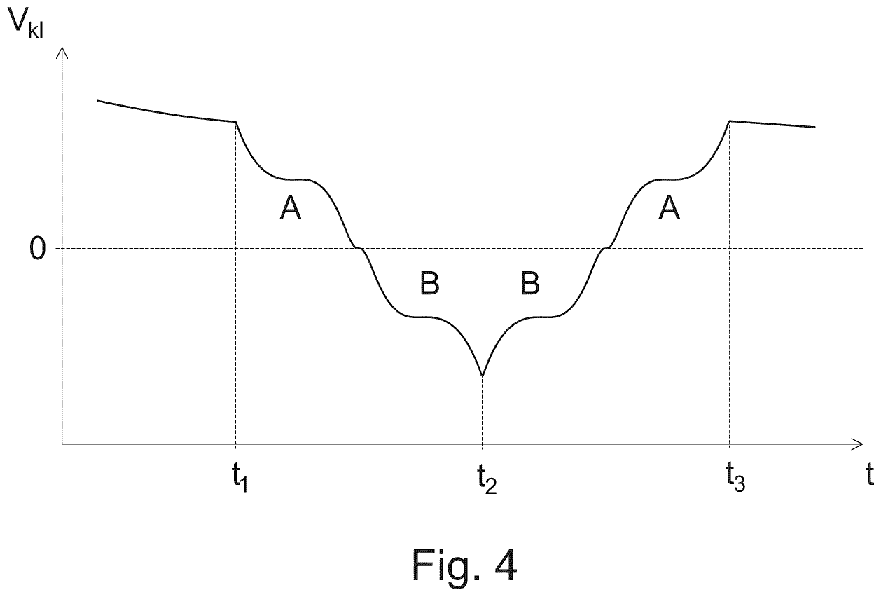

FIG. 4 shows the time curve of the terminal voltage of a battery module with shifted electrolyte during the execution of the method according to the invention in a further embodiment. In contrast to the embodiment according to FIG. 3, the pumps are not switched on at time t₂. Instead, at time t₂, the polarity of the relevant battery module is reversed. This causes the sign of the current flowing through the battery module in question to reverse. As a result, the battery module passes through the states it passed through in the time interval [t₁, t₂] in reverse order in the time interval [t₂, t₃]. Therefore, plateaus A and B also occur in the time interval [t₂, t₃], which enables a fourfold redundant determination of the SoH. At time t₃, the terminal voltage is therefore positive again. At time t₃, the polarity of the relevant battery module is reversed again and the pumps are switched on. Alternatively, the relevant battery module may also be removed from the series connection of the battery system at time t₃, e.g. if the AOS determination has delivered a result that requires immediate maintenance.

To carry out the method shown in FIG. 4, the battery module in question must include a polarity reversal device. The terminal voltage curve shown in FIG. 4 results when the polarity reversal device is located between the measurement device for supplying the terminal voltage and the external terminals of the battery module. In this arrangement, the measured terminal voltage is not affected by the polarity reversal. The polarity reversal device could also be arranged between the measurement device for supplying the terminal voltage and the inner terminals of the battery module. In this case, the time curve of the detected terminal voltage would show corresponding jumps at times t₂ and t₃.

The execution of the method according to the invention leads to a variation in the total voltage of the battery system, which deviates from the variation in the total voltage during normal operation of the battery system. This is particularly the case when the method according to the invention is carried out simultaneously on more than one battery module. In order to ensure normal operation of the battery system even during the execution of the method according to the invention, the battery system must be configured in such a way that it may compensate for the variation in the total voltage caused by the invention. The measurement device 5 for providing a potential difference must be configured so that it may detect both positive and negative potential differences and provide the corresponding measured values. If the terminal voltage is used as the potential difference for the method according to the invention, then this condition naturally applies for the measurement device for providing the terminal voltage.

To increase the reliability of the SoH or AOS determination according to the invention, the strength of the discharge current flowing through the battery system may be reduced in the time interval [t₁, t₂] or [t₁, t₃]. This increases the width of plateaus A and B, which facilitates the evaluation of the potential difference or terminal voltage curves and increases the measurement accuracy. At very low current strengths, the measurement accuracy suffers again. The inventors have recognised that, with conventional battery systems, optimum measurement accuracy is achieved when the discharge current is within a range of 10% to 50% of the nominal current of the battery system.

### LIST OF REFERENCE SIGNS

1 battery module
2 cell arrangement
3 reservoir
4 pump
5 measurement device for detecting a potential difference
6 converter
7 control device
8 polarity reversal device

1. A method for monitoring a state of a redox flow battery system on the basis of vanadium, wherein the redox flow battery system comprises at least two battery modules, a bidirectional converter, and a control device,
wherein the at least two battery modules are connected in series and are connected to the bidirectional converter,
wherein each battery module of the at least two battery modules comprises a cell arrangement having a plurality of redox flow cells, a measurement device for detecting a potential difference of the cell arrangement, and a reservoir for storing negative and positive electrolyte and for supplying the cell arrangement with electrolyte,
wherein the control device is configured to detect operating states of the bidirectional converter and to control pumps in the at least two battery modules,
wherein the method comprises
S1: identifying at least one battery module of the at least two battery modules with a suspicion of shifted electrolyte;
S2: switching off the pumps of the at least one identified battery module at a time t₁ while the redox flow battery system is in a discharge operating state;
S3: repeatedly detecting potential difference values of the at least one identified battery module up to a later time t₂, whereby the pumps of the at least one identified battery module remain switched off; and
S4: determining an average oxidation state (AOS) of the at least one identified battery module from the potential difference values detected in step S3,
wherein a duration of time interval Δt=t₂−t₁ is selected such that, at time t₂, a potential difference of the at least one identified battery module is negative, but overcharging of the electrolyte located in the cell arrangement-(2) of the at least one identified battery module is avoided,
wherein the redox flow battery system is discharged in the time interval [t₁, t₂], and
wherein determining of the AOS in step S4 is redundantly performed from positive and negative potential difference values.

2. The method according to claim 1, wherein each battery module of the at least two battery modules comprises a polarity reversal device, and
wherein the method further comprises:
S5: reversing a polarity of the at least one identified battery module at time t₂;
S6: repeatedly measuring the potential difference values of the at least one identified battery module until a later time t₃, wherein the pumps of the at least one identified battery module remain switched off; and
S7: determining the AOS of the at least one identified battery module from the potential difference values detected in step S6,
wherein a duration of time interval Δt=t₃−t₂ is selected such that, at time t₃, the potential difference of the at least one identified battery module is positive, but overcharging of the electrolyte located in the cell arrangement of the at least one identified battery module is avoided, and
wherein the redox flow battery system is discharged in the time interval [t₂, t₃], and wherein the determination of the AOS in step S7 is redundantly performed from positive and negative potential difference values.

3. The method according to claim 1, wherein a current strength of a discharge current in the time interval [t₁, t₂] is in a range of 10% to 50% of a nominal current of the redox flow battery system.

4. The method according to claim 2, wherein a current strength of a discharge current in the time interval [t₂, t₃] is in a range of 10% to 50% of a nominal current of the redox flow battery system.

5. The method according claim 1, wherein the potential difference is a terminal voltage.

6. The method according to claim 1, wherein identifying the at least one battery module with the suspicion of shifted electrolyte comprises identifying a reduction in a usable capacity of the at least one battery module.

7. The method according to claim 1, wherein the pumps of the at least one identified battery module are switched on at time t₂.

8. The method according to claim 1, wherein the pumps of the at least one identified battery module are switched on at time t₃.

9. The method according to claim 1, further comprising removing from the at least one identified battery module from a series connection of the redox flow battery system.

10. The method according to claim 1, wherein the method is carried out simultaneously on more than one battery module of the at least two battery modules.

11. The method according to claim 1, wherein the measurement device is configured to detect a positive and a negative potential difference.

12. The method according to claim 1, wherein the measurement device is configured to measure a potential difference between a negative electrolyte and a positive electrolyte.

13. The method according to claim 1, wherein the measurement device is configured to measure a potential difference between two outer electrodes of the cell arrangement.

14. The method according to claim 1, wherein step S1 is performed in a charging operating state or the discharge operating state.

15. The method according to claim 2, wherein the polarity reversal device is arranged between the measurement device and external terminals of the at least two battery modules, or between the measurement device and inner terminals of the at least two battery modules.
